(19) United States
(12) Patent Application Publication
(10) Pub. No.: US 2025/0364370 A1
(43) Pub. Date: Nov. 27, 2025

(54) THROUGH VIAS AND GUARD RINGS OF SEMICONDUCTOR STRUCTURE AND METHOD OF FORMING THEREOF

(71) Applicant: Taiwan Semiconductor Manufacturing Co., Ltd., Hsinchu (TW)

(72) Inventor: Chien-Hsun Lin, Kaohsiung City (TW)

(21) Appl. No.: 19/286,380

(22) Filed: Jul. 31, 2025

Related U.S. Application Data
(63) Continuation of application No. 18/526,498, filed on Dec. 1, 2023.
(60) Provisional application No. 63/517,374, filed on Aug. 3, 2023.

(51) Int. Cl. H01L 23/48; H01L 21/762; H01L 21/768; H01L 23/522

(52) U.S. Cl. CPC H01L 23/481; H01L 21/76224; H01L 21/76898; H01L 23/5226

(57) ABSTRACT

In an embodiment, a method includes: forming a first opening in a semiconductor substrate, in a plan view the first opening having a ring shape; forming a dielectric guard ring in the first opening; forming an active device along a first surface of the semiconductor substrate; forming first metallization layers over the active device; forming a second opening through the semiconductor substrate, the second opening adjacent to the ring shape of the dielectric guard ring; forming a conductive through via in the second opening; and forming second metallization layers over the first metallization layers.

### PRIORITY CLAIM AND CROSS-REFERENCE

This application is a continuation of U.S. patent application Ser. No. 18/526,498, filed Dec. 1, 2023, which application claims the benefit of U.S. Provisional Application No. 63/517,374, filed on Aug. 3, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative fabrication techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 3A, 3B, 4A, 4B, 5A, 5B, 6, 7, 8A, 8B, 8C, 8D, 9A, 9B, 9C, and 9D are cross-sectional and plan views of intermediate steps during a process of forming a semiconductor structure, in accordance with various embodiments.

FIGS. 10, 11, 12, 13, 14A, 14B, 15A, 15B, 15C, and 15D are cross-sectional and plan views of intermediate steps during a process of forming a semiconductor structure, in accordance with various embodiments.

FIG. 16 is a cross-sectional view of an intermediate stage during a process of forming a semiconductor structure, in accordance with various embodiments.

FIG. 17 is a cross-sectional view of an intermediate stage during a process of forming a semiconductor structure, in accordance with various embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a semiconductor die or wafer is formed, and one or more through vias are formed through the die or wafer, such as being formed through a semiconductor substrate of the die or wafer. The through vias can be used to electrically connect components on opposite sides of the semiconductor substrate and allow for stacking of multiple dies to form 3D packages or 3D integrated circuits (3DICs). A dielectric guard ring is formed within the semiconductor substrate to encircle the through via. The dielectric guard ring provides a buffer between the through vias and active devices formed along the semiconductor substrate. In particular, the dielectric guard ring serves to absorb heat that may dissipate from the through via toward the active devices. Large differences in the coefficients of thermal expansion (CTEs) between material of the through via and material of the semiconductor substrate may affect or deviate the performance of the proximal active devices and circuitry. However, the dielectric guard ring mitigates these issues due to material of the dielectric guard ring having a CTE being closer to the CTE of the material of the semiconductor substrate. The resulting semiconductor die has improved performance and reliability.

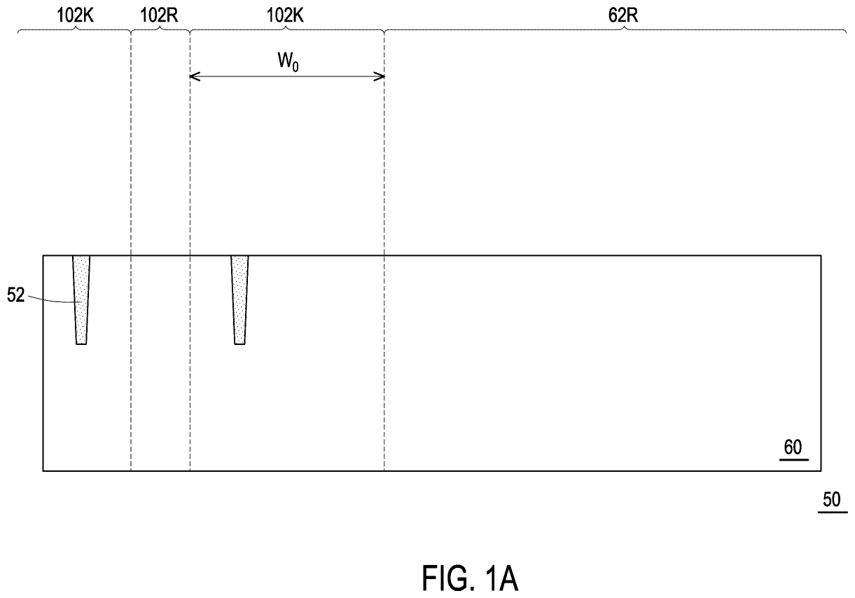

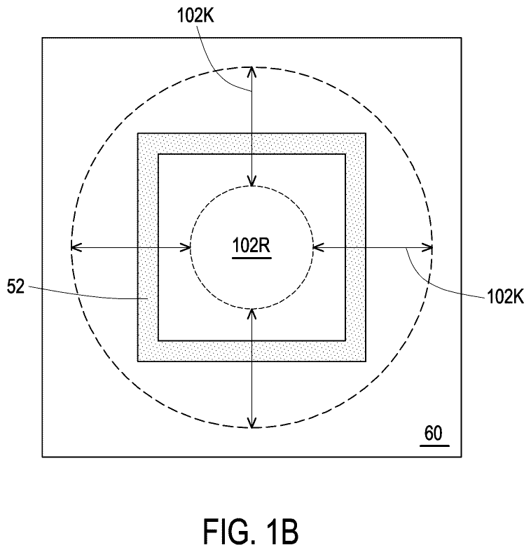

FIGS. 1A and 1B provide a cross-sectional view and a plan view, respectively, of a semiconductor substrate 60 at an intermediate stage of forming a semiconductor structure 50, in accordance with some embodiments. The semiconductor substrate 60 may be silicon, doped or undoped, or an active layer of a semiconductor-on-insulator (SOI) substrate. The semiconductor substrate 60 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multilayered or gradient substrates, may also be used. The semiconductor structure 50 may be fabricated at the wafer level. For example, the illustrated semiconductor structure 50 may represent an individual integrated circuit die or semiconductor device (e.g., among many) within a wafer.

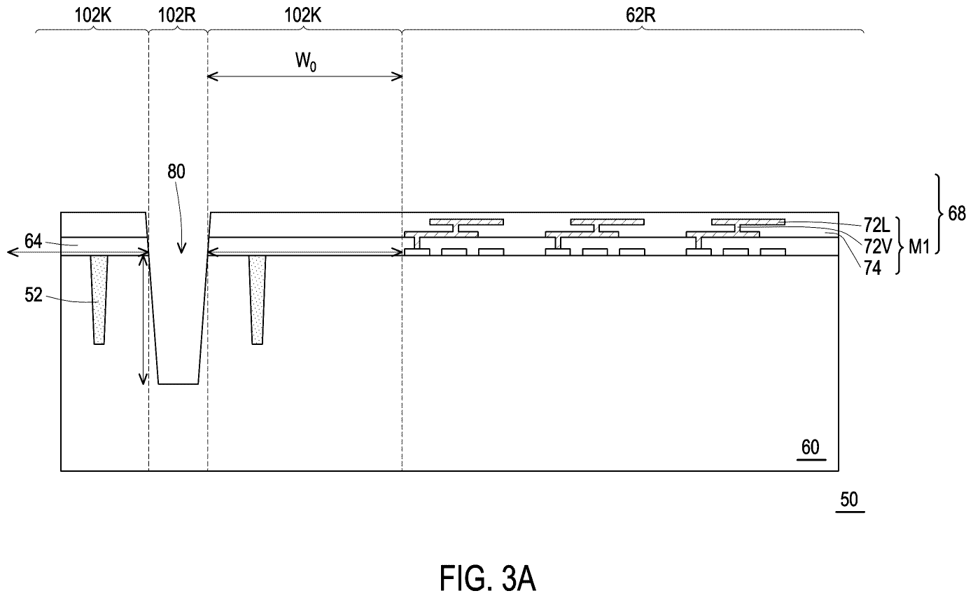

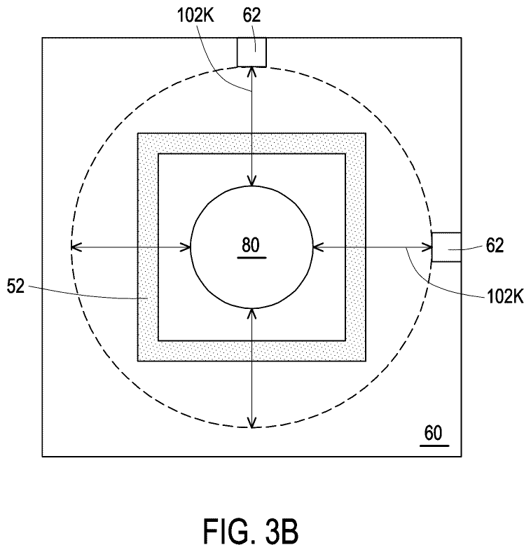

In accordance with various embodiments, a guard ring 52 is formed in the semiconductor substrate 60. The guard ring 52 will encircle a subsequently formed through via (see FIGS. 3A through 5B). In accordance with various embodiments, the guard ring comprises a dielectric material and be referred to as a dielectric guard ring or an insulating guard ring. Note that this and subsequent figures illustrate one guard ring 52 (e.g., encircling one through via), however, any number of guard rings 52 and through vias may be utilized in the semiconductor structure 50.

As described and illustrated in greater detail below, the guard ring 52 is located within a region that will be around the subsequently formed through via. This region may remain free of electrical components. In addition, this region may be referred to as a keep out zone (KOZ) 102K, which surrounds the through via (e.g., currently indicated as through via region 102R). In accordance with various embodiments, the keep out zone may have a width W₀ (e.g., separated by a keep out distance) by which the most proximal devices 62 are separated from the through via region 102R (e.g., subsequently formed through via).

Appropriate photolithography and etching techniques (e.g., anisotropic reactive-ion etching (RIE) employing fluorocarbon chemicals) may be used to etch the semiconductor substrate 60 to form an opening for the guard ring 52. A dielectric material may be deposited to fill the opening. For example, the dielectric material may include an oxide or a nitride, such as silicon oxide, silicon oxycarbide, silicon oxynitride, silicon nitride, the like, or a combination thereof. Any excess dielectric material over the semiconductor substrate 60 outside of the opening may be removed by a planarization process, such as a chemical mechanical polishing (CMP) process, thereby forming a top surface of the guard ring 52 that is substantially coplanar with the semiconductor substrate 60.

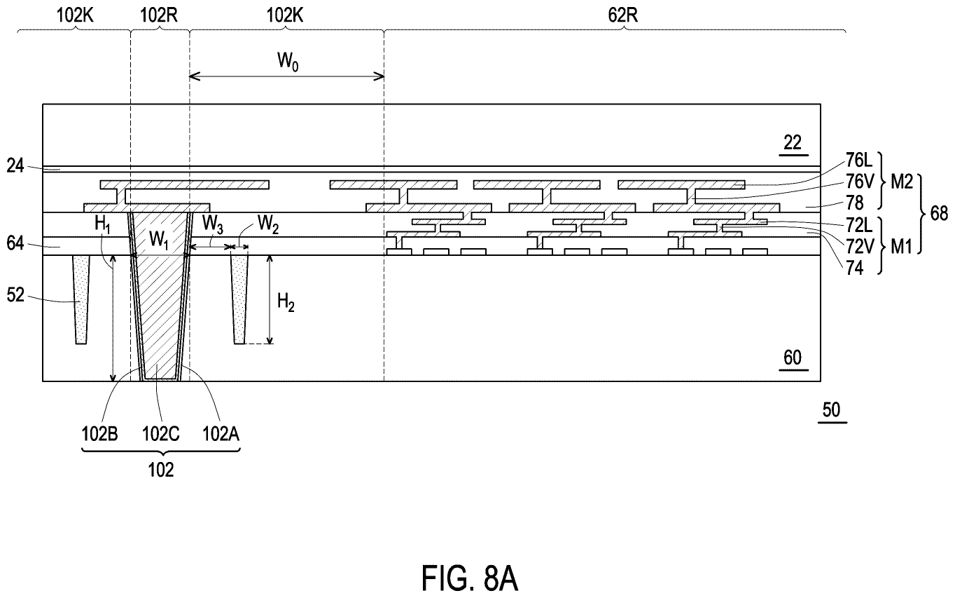

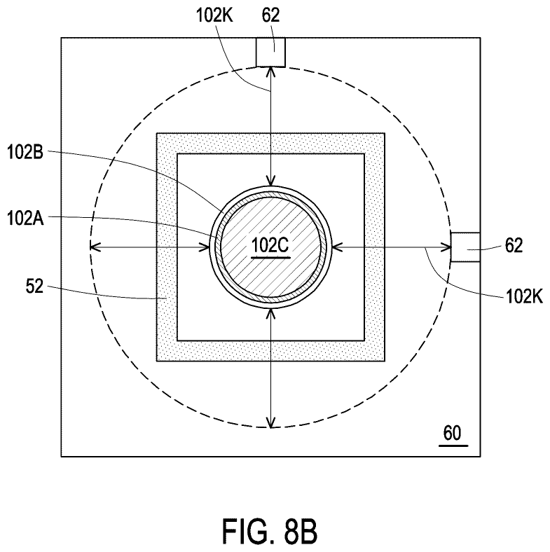

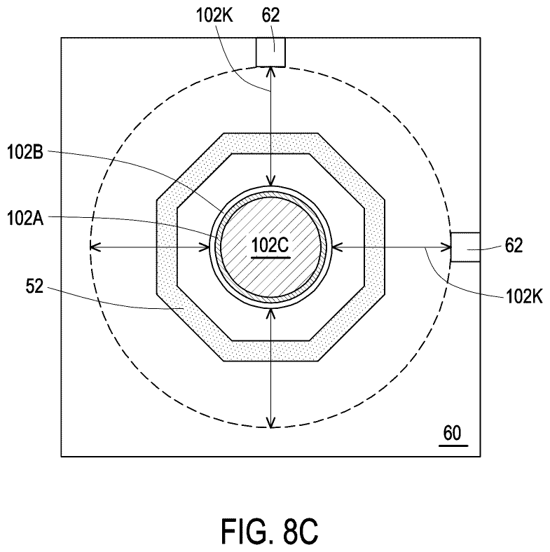

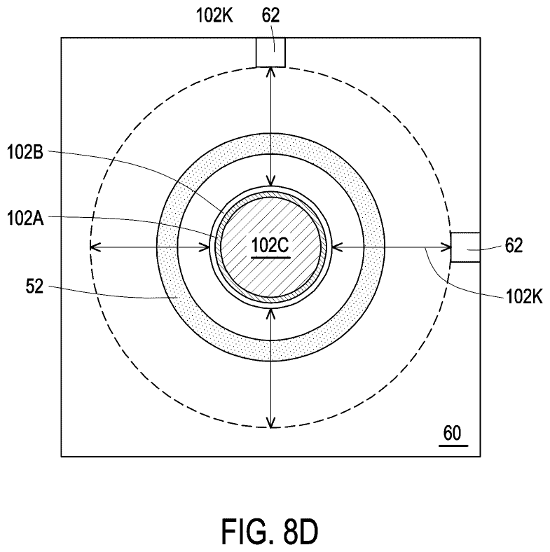

Referring to FIG. 1B, a top-down plan view illustrates the semiconductor structure 50 at an uppermost portion of the semiconductor substrate 60. As illustrated, the guard ring 52 forms a concentric ring around the through via region 102R within the keep out zone 102K. The guard ring 52 is illustrated as being rectangular (e.g., square). However, the guard ring 52 may be any suitable polygon (e.g., square, hexagonal, octagonal, etc.) or oval (e.g., circular) (see FIGS. 8B through 8D). In addition, the keep out zone 102K is illustrated as a concentric circle around the through via region 102R. However, the keep out zone 102K may be any suitable shape, such as a rectangle (e.g., square).

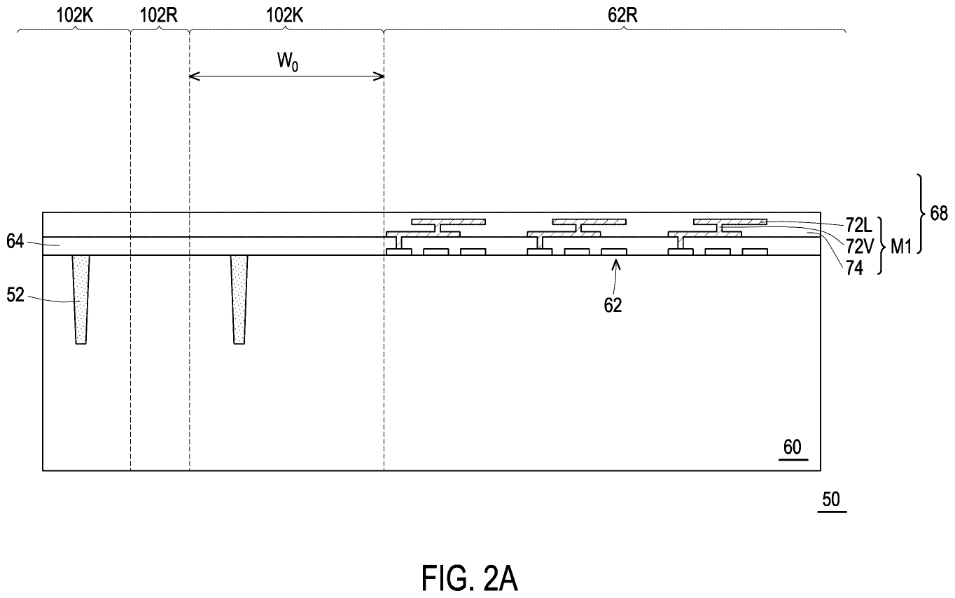

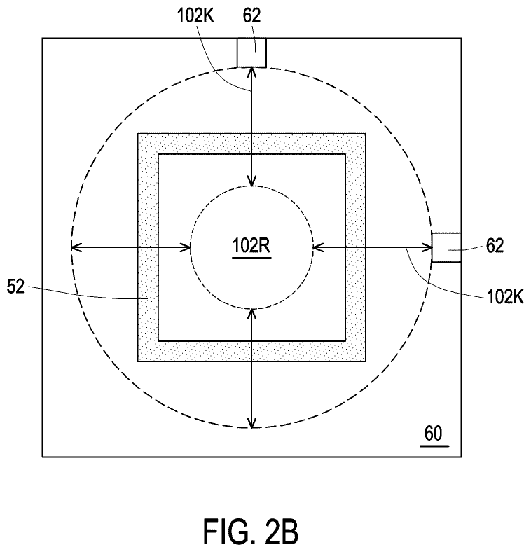

In FIGS. 2A and 2B, devices 62 are formed at the active surface of the semiconductor substrate 60. The devices 62 may be electrical components such as active devices and passive devices. For example, the devices 62 may be transistors, diodes, capacitors, resistors, or the like, formed by any suitable formation method. The devices 62 may be interconnected to form, e.g., memory devices or logic devices on the semiconductor structure 50. In some embodiments, the guard ring 52 may be formed during or in between various steps of forming the devices 62. For example, the opening for the guard ring 52 may be etched during or after formation of isolation regions or source/drain regions of the transistors.

One or more inter-layer dielectric (ILD) layer(s) 64 are formed on the semiconductor substrate 60, and electrically conductive features, such as contact plugs 66, are formed physically and electrically coupled to the devices 62. The ILD layers 64 may be formed of any suitable dielectric material, for example, an oxide such as silicon oxide, phosphosilicate glass (PSG), borosilicate glass (BSG), boron-doped phosphosilicate glass (BPSG), or the like; a nitride such as silicon nitride; or the like. The ILD layers 64 may be formed by any suitable method, such as CVD, physical vapor deposition (PVD), ALD, PEALD, PECVD, SACVD, FCVD, spin-on, and/or the like, or a combination thereof. The electrically conductive features in the ILD layers 64 may be formed through any suitable process, such as deposition, damascene (e.g., single damascene, dual damascene, etc.), the like, or combinations thereof.

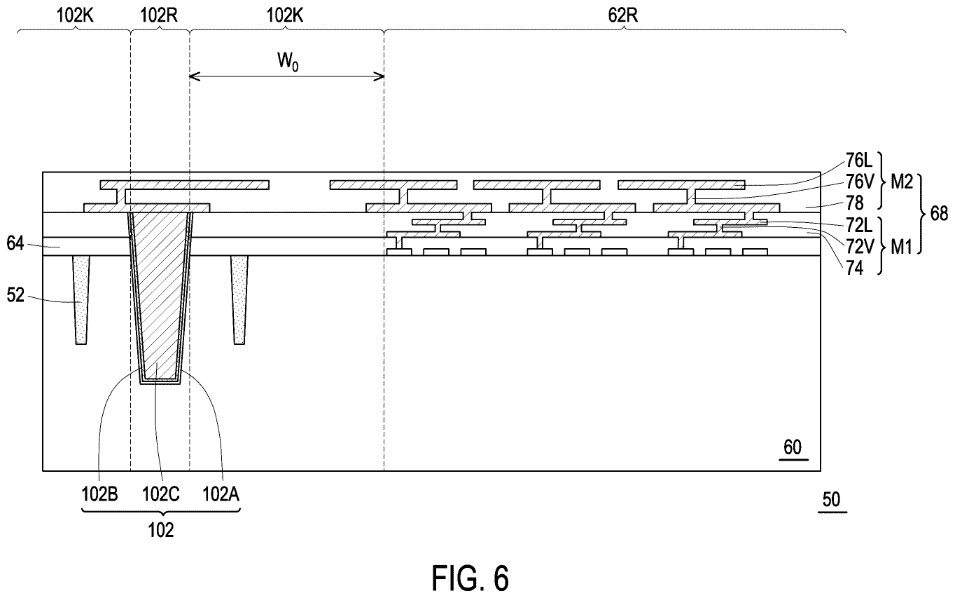

In addition, first metallization layers M1 are formed over the semiconductor substrate 60 and over the ILD layers 64. The first metallization layers M1 are a lower portion of an interconnect structure 68, wherein second metallization layers M2 are subsequently formed (see FIG. 6). The interconnect structure 68 electrically connects the devices 62 to form integrated circuits. First metallization layers M1 comprise conductive features 72 (e.g., conductive vias 72V and lines 72L) embedded in intermetal dielectric (IMD) layer(s) 74 (not individually shown). In addition to providing insulation between various conductive elements, an IMD layer 74 may include one or more dielectric etch stop layers (not individually shown) to control the etching processes that form openings in the IMD layer 74. Generally, vias 72V conduct current vertically and are used to electrically connect two other conductive features 72 (e.g., conductive lines 72L) located at vertically adjacent levels, whereas lines 72L conduct current laterally and are used to distribute electrical signals and power within one level.

Although two layers of conductive features 72 (e.g., two layers of the conductive lines 72L) are illustrated among the first metallization layers M1, it should be appreciated that more or fewer layers may be formed. Each of the first metallization layers M1 includes metallization patterns of conductive lines 72L in the corresponding IMD layer 74. The conductive features 72 are electrically coupled to the devices 62 along the semiconductor substrate 60. The first metallization layers M1 of the interconnect structure 68 may be formed by a damascene process, such as a single damascene process, a dual damascene process, or the like. In the illustrated embodiments, lowermost conductive lines 72L of the conductive features 72 connect contact plugs 66 to other conductive features 72, and vias 72V connect conductive lines 72L on a level below the vias 72V to conductive lines 72L above the vias 72V (e.g., a pair of lines 72L can be connected by a via 72V). Some embodiments may adopt a different scheme. For example, conductive vias 72V may be in the first metallization layers M1 between the contact plugs 66 and the conductive features 72. In some embodiments, the contact plugs 66 are formed through the ILD layers 64 before or during the formation of the metallization layers M1.

Still referring to FIGS. 2A and 2B, the first metallization layers M1 may be formed using, for example, a damascene process flow. The techniques used to deposit the dielectric stack for the IMD layers 74 may be the same or similar as those used in forming the ILD layers 64. Appropriate photolithography and etching techniques (e.g., anisotropic RIE employing fluorocarbon chemicals) may be used to pattern each of the IMD layers 74 to form openings for respective conductive lines 72L and/or vias 72V. Several conductive materials may be deposited to fill the trenches forming the conductive features 72 of the first metallization layers M1. For example, the openings may be first lined with one or more liners and then filled with a conductive fill layer. A conductive diffusion barrier liner may be formed over sidewalls and bottom surfaces of the trenches. Any excess conductive material over the IMD layer 74 outside of the openings may be removed by a planarizing process (e.g., CMP) thereby forming a top surface comprising dielectric regions of IMD layer 74 that are substantially coplanar with the conductive features 72. As a result, the first metallization layers M1 comprise the conductive features 72 (e.g., conductive lines 72L and vias 72V) embedded in the IMD layers 74.

In some embodiments, one or more layers of the first metallization layers M1 may be formed using, for example, a dual damascene process flow. First, a dielectric stack used to form the IMD layer 74 is formed using similar materials and methods as described above. Next, openings for vias and lines are formed in the IMD layer 74 with appropriate photolithography and etching techniques. The openings for vias may be vertical holes extending through the IMD layer 74 to expose a top surface of the lower conductive features 72 (e.g., the lowermost conductive lines 72L of the first metallization layers M1), and the openings for conductive lines 72L may be longitudinal trenches formed in an upper portion of the IMD layer 74. The openings may be formed using either a via-first process or a via-last process.

Several conductive materials may be deposited to fill the holes and trenches simultaneously forming a layer of the conductive lines 72L and vias 72V of the first metallization layers M1. The conductive lines 72L and vias 72V may be formed using similar materials and methods as described above. Any excess conductive material over the IMD 74 outside of the openings may be removed by a planarization process (e.g., CMP) thereby forming a top surface comprising dielectric regions of IMD layers 74 that are substantially coplanar with the conductive features 72 of the first metallization layers M1. As a result, the first metallization layers M1 include a plurality of layers of the conductive features 72 embedded in a plurality of the IMD layers 74.

Referring to FIG. 2B, a top-down plan view illustrates the semiconductor structure 50 at the uppermost portion of the semiconductor substrate 60. As illustrated, the guard ring 52 forms a concentric ring around the through via region 102R within the keep out zone 102K. In addition, the devices 62 are located outside of the keep out zone 102K. Although the first metallization layers M1 are not shown in this view, it should be appreciated that the conductive features 72 may also be located outside of the keep out zone 102K.

Although certain numbers of devices 62 and layers of the first metallization layers M1 of the interconnect structure 68 are described and illustrated for making connections within the semiconductor structure 50, it is understood that one of ordinary skill in the art will appreciate that the above examples are provided for illustrative purposes only to further explain applications of the present embodiments. These descriptions and illustrations are not meant to limit the present embodiments in any manner.

FIGS. 3A through 5B illustrate formation of through vias 102 (e.g., conductive through vias) using a via-middle process, in accordance with various embodiments. As illustrated, the through vias 102 may extend through the first metallization layers M1 (e.g., the IMD layers 74), the ILD layers 64, and at least a portion of the semiconductor substrate 60. The through vias 102 may also be referred to as through substrate vias, through semiconductor vias, or through silicon vias (TSVs). The through vias 102 can be used for electrical connection of devices subsequently attached to the semiconductor structure 50, such as components that are or will be located on opposite sides of the semiconductor substrate 60. For example, the through vias 102 may be formed through multiple layers for the electrical connection of components formed or attached outside the semiconductor structure 50. Although only one through via 102 is illustrated for exemplary purposes, any suitable number of through vias 102 may be formed. In addition, although only an individual through via 102 is illustrated within an individual guard ring 52, in some embodiments, a plurality of through vias 102 may be located within an individual keep guard ring 52. Further, the figures illustrate the through vias 102 as extending through the first metallization layers M1 for illustrative purposes. In some embodiments, the through vias 102 may be formed after forming additional metallization layer(s), e.g., being formed after forming second metallization layers M2 (see FIG. 6). In particular, the through vias 102 may be formed through any suitable number of metallization layers.

In FIGS. 3A and 3B, recesses 80 are formed through the IMD layers 74 (e.g., the first metallization layers M1), the ILD layer 64, and into the semiconductor substrate 60. The recesses 80 may be formed by applying, exposing, and developing a suitable photoresist (not shown) over the first metallization layers M1 to define a desired pattern of through vias. One or more etching process may be used to remove portions of the IMD layers 74, the ILD 64, and the semiconductor substrate 60 that are exposed to the desired depth. Other techniques, such as milling, laser techniques, a combination thereof, and/or the like, may also be used. The recesses 80 may be formed so as to extend into the semiconductor substrate 60 at least further than the devices 62 formed within and/or on the semiconductor substrate 60. In some embodiments, the recesses 80 extend to a depth less than an entire thickness of the semiconductor substrate 60. In addition, the recesses 80 may extend to a depth greater than the eventual desired thickness of the semiconductor substrate 60 (see FIG. 8A).

Referring to FIG. 3B, a top-down view illustrates the semiconductor structure 50 at the uppermost portion of the semiconductor substrate 60. As illustrated, the recess 80 is the location of the through via region 102R. However, the recess 80 may be less than the through via region 102R in this view in order to account for the recess 80 having a larger width in a different cross-section (e.g., located proximal to a top surface of the IMD layers 74).

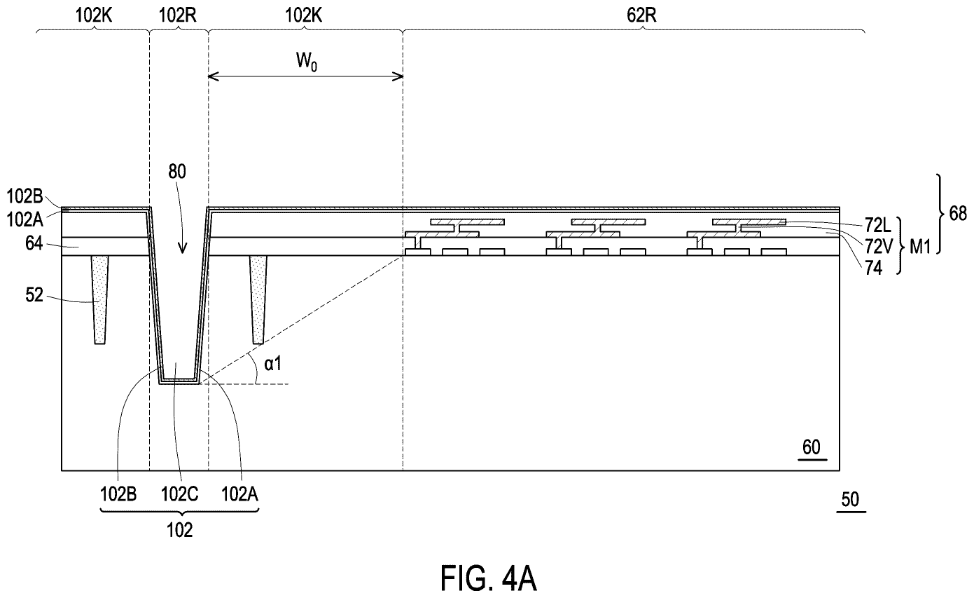

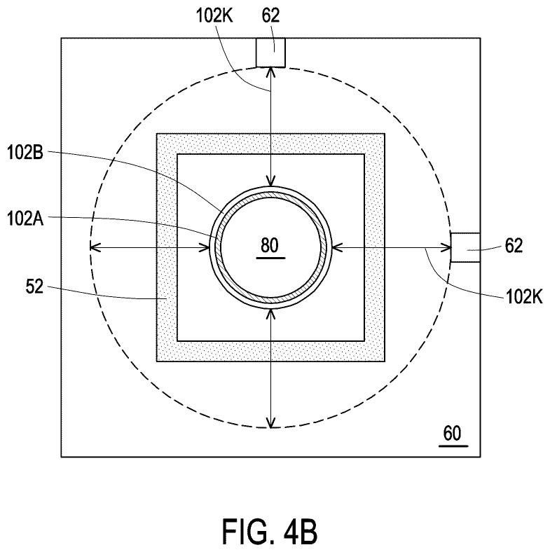

In FIGS. 4A and 4B, after the recesses 80 have been formed into the semiconductor substrate 60, the recesses 80 may be lined with liner layers. The liner layers may be a plurality of layers, including an adhesive layer 102A and a barrier layer 102B. The adhesive layer 102A may be, e.g., an oxide formed from tetraethylorthosilicate (TEOS) or silicon nitride, although any suitable dielectric material may be used. In some embodiments, a suitable conductive material may be used. The adhesive layer 102A may be conformally deposited and formed using a plasma enhanced chemical vapor deposition (PECVD) process, although other suitable processes, such as physical vapor deposition or a thermal process, may alternatively be used. The adhesive layer 102A may have a thickness in a range of 5 nm to 500 nm.

Once the adhesive layer 102A has been formed along the sidewalls and bottom of the recesses 80, the barrier layer 102B may be conformally deposited in the recesses 80 and formed by CVD, atomic layer deposition (ALD), physical vapor deposition (PVD), thermal oxidation, the like, or a combination thereof. The barrier layer 102B may be formed from an oxide, a nitride, or an oxynitride, such as titanium nitride, titanium oxynitride, tantalum nitride, tantalum oxynitride, tungsten nitride, a combination thereof, and/or the like. However, any suitable material for the barrier layer 102B may be used. In some embodiments, the barrier layer 102B is formed directly along the sidewalls and bottom of the recesses 80. The barrier layer 102B may have a thickness in a range of 5 nm to 500 nm. As discussed above, the adhesive layer 102A and the barrier layer 102B may collectively be referred to as the liner layers.

Referring to FIG. 4B, a top-down view illustrates the semiconductor structure 50 at the uppermost portion of the semiconductor substrate 60. As illustrated, the recess 80 is lined by the adhesive layer 102A and the barrier layer 102B.

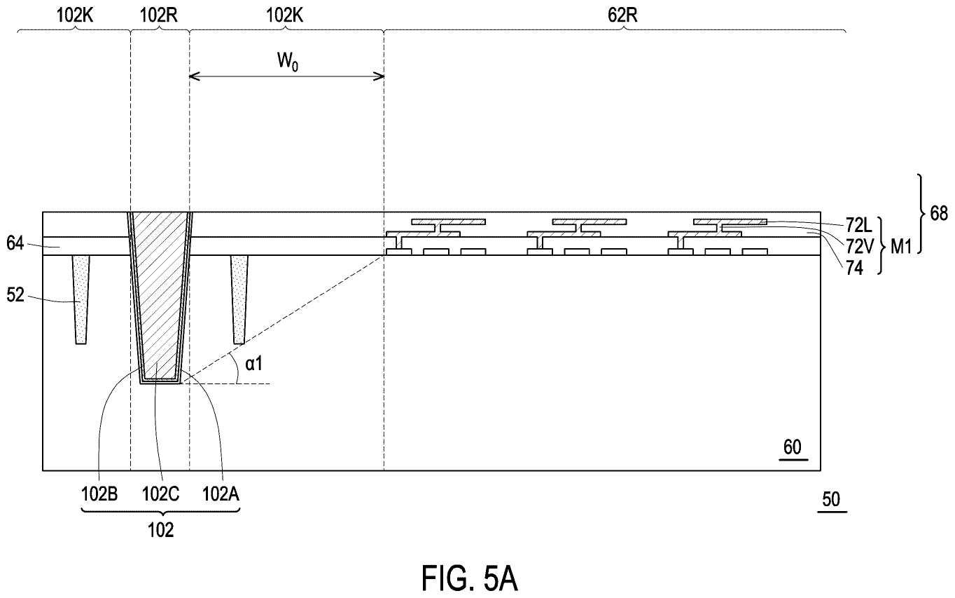

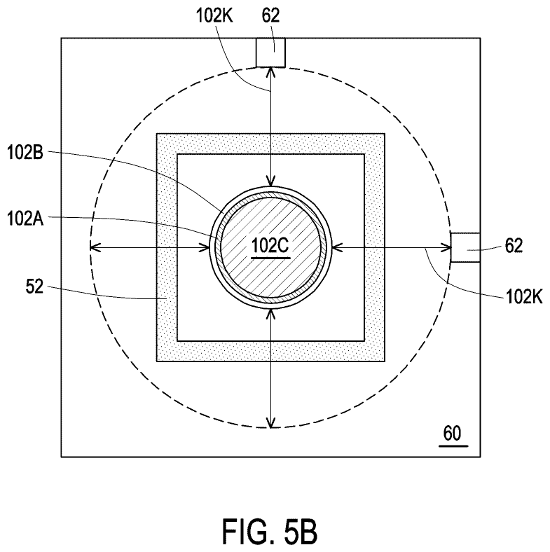

In FIGS. 5A and 5B, after forming the liner layers (e.g., the adhesive layer 102A and the barrier layer 102B), the remainder of the recesses 80 may be filled with a conductive material 102C. The conductive material 102C may comprise copper, tungsten, cobalt, aluminum, silver, gold, alloys, doped polysilicon, the like, or a combination thereof. The conductive material 102C may be formed by deposition or electroplating copper onto a seed layer (not shown), filling and overfilling the recesses 80. However, any suitable process such as CVD, PVD, or the like may be used. Once the recesses 80 have been filled, excess of the liner layers, seed layer (if present), and conductive material 102C outside of the recesses 80 may be removed through a planarization process such as CMP, although any suitable removal process may be used. Remaining portions of the liner layers 102A/102B and the conductive material 102C form the through vias 102. In some cases, only the conductive materials remaining in the recesses 80 may be referred to as the through vias 102. As such, the through vias 102 may include only the conductive material 102C or include the conductive material 102C and the barrier layer 102B. In some embodiments, each of the adhesive layer 102A and the barrier layer 102B is a single continuous material extending from a bottom surface of the through via 102 to a top surface of the through via 102. In embodiments (not specifically illustrated), the adhesive layer 102A and the barrier layer 102B may be treated to form an intermixed bilayer, which may be considered part of the through vias 102.

As illustrated, in some embodiments, the through vias 102 are not yet exposed at the back side of the semiconductor substrate 60. Rather, the through vias 102 are buried in the semiconductor substrate 60. As discussed in greater detail below, the through vias 102 will be exposed at the back side of the semiconductor substrate 60 in subsequent processing. In other embodiments, the through vias 102 are formed through the semiconductor substrate 60.

In FIG. 6, second metallization layers M2 are formed over the first metallization layers M1 to form an upper portion of the interconnect structure 68. Although two layers of the second metallization layers M2 are illustrated, the second metallization layers M2 represent any number of layers for simplicity of illustration. Any suitable number of metallization layers may be formed in the interconnect structure 68, such as four to twenty metallization layers in the first metallization layers M1 and the second metallization layers M2 combined. The second metallization layers M2 comprise IMD layers 78 and conductive features 76 (e.g., conductive lines 76L and vias 76V). The materials and processing techniques described above in the context of the first metallization layers M1 may be used to form the second metallization layers M2 (e.g., including the analogous features).

In various embodiments, the conductive features 76 of the second metallization layers M2 are electrically connected to the through vias 102. For example, lowermost conductive features 76 (e.g., lowermost conductive lines 76L) may be formed along top surfaces of the through vias 102 to make electrical connection. In other embodiments (not specifically illustrated), the second metallization layers M2 may be electrically connected to the through vias by the conductive vias 76V. Similarly as stated above, the conductive features 76 may be formed using a dual damascene process (or a combination of single and dual damascene processes). In some embodiments, a first of these dual damascene processes may include forming the uppermost vias 72V (e.g., through an uppermost IMD layer 74) of the first metallization layers M1 simultaneously with the lowermost conductive lines 76L (e.g., through a lowermost IMD layer 78) of the second metallization layers M2.

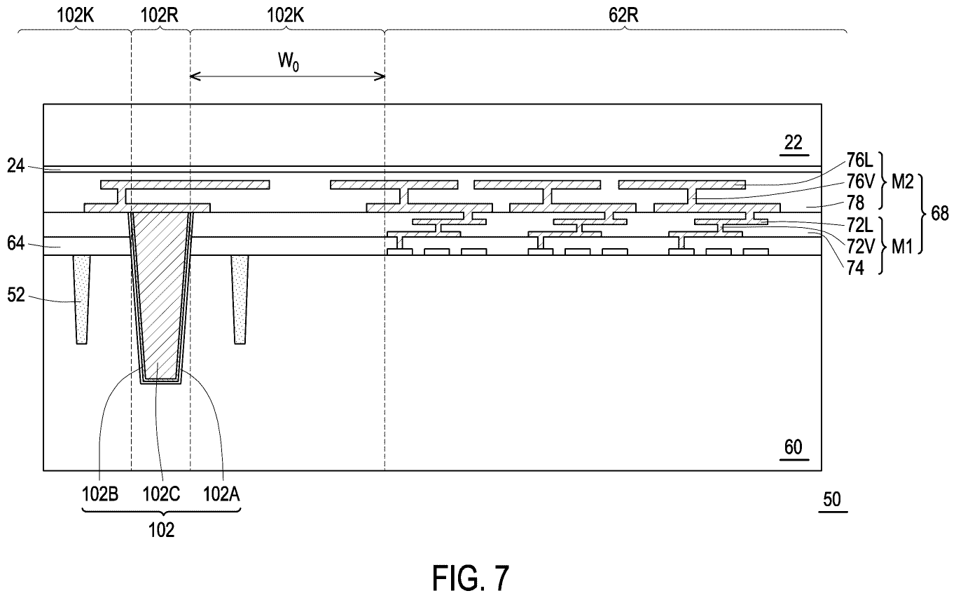

In FIG. 7, the semiconductor structure 50 is attached to carrier 22 and release film 24. The carrier 22 may be a glass carrier, a silicon wafer, an organic carrier, or the like. The carrier 22 may have a round top-view shape in accordance with some embodiments. The release film 24 may be a glue and may be formed of a polymer-based material and/or an epoxy-based thermal-release material (such as a Light-To-Heat-Conversion (LTHC) material), which is capable of being decomposed under radiation such as a laser beam, so that the carrier 22 may be subsequently de-bonded from the overlying structure. In accordance with some embodiments, the release film 24 is applied on the carrier 22 through coating before attaching the carrier 22 to the semiconductor structure 50.

In FIGS. 8A through 8D, a back side thinning process is performed on the back side of the semiconductor structure 50, wherein the semiconductor substrate 60 is thinned. The back side thinning process may be a grinding process and performed through a CMP process or a mechanical polishing process. In some embodiments, following the back side thinning process, the through vias 102 (e.g., the barrier layer 102B and/or the conductive material 102C) are exposed.

Benefits are achieved through the guard ring 52 encircling the through via 102. In particular, the layout and dimensions of the guard ring 52 in relation to the corresponding through via 102 provide advantages to the performance of the resulting semiconductor structure 50. In various embodiments, a height H₁ of the through via 102 within the semiconductor substrate 60 (e.g., the post-thinning thickness of the semiconductor substrate 60) may be greater than a total height H₂ of the guard ring 52 (e.g., within the semiconductor substrate 60). For example, the height H₁ may be greater than or equal to 5 μm, and the height H₂ may be greater than or equal to 0.5 μm. In addition, a ratio H₂/H₁ may range from 0.15 to almost 1 (or substantially 1). Note that in embodiments in which this ratio is substantially 1, the guard ring 52 may be exposed or almost exposed by the back side thinning process. Further, the through vias 102 may have a taper angle α₁ being less than 90°. In addition, the guard ring 52 may have a taper angle α₂ being less than 90°. In some embodiments, the through vias and/or the guard ring are substantially vertical (e.g., taper angles of) 90°. However, any suitable shape for the through via 102 and the guard ring 52 may be used.

As noted above, the keep out zone may have width W₀ by which the most proximal devices 62 are separated from the through via 102. In addition, the through via 102 and the guard ring 52 may have similar proportions. For example, a ratio of the height H₁ to a width W₁ of the through via 102 may range from 2 to 20, and a ratio of the height H₂ to a width W₂ of the guard ring 52 may range from 2 to 20. Further, the guard ring 52 may be separated from the through via 102 by a width W₃. As such, a ratio W₀/W₁ may range from 0.2 to 1.2, a ratio W₃/W₀ may be greater than 0 (such as ranging from 0.05 to 0.2), and a ratio W₂/W₀ may range from 0.1 to 0.5. These dimensions ensure a large enough distances between the various features to reduce expansion issues associated with the various CTE mismatches (e.g., CTE gaps between adjacent features). Conversely, these dimensions ensure close enough distances between the various features to allow the guard ring 52 to serve as a buffer and mitigate issues specifically relating to the CTE mismatch between the through via 102 and the semiconductor substrate 60. For example, the through via 102 (e.g., copper) may have a CTE of 17.3, and the semiconductor substrate 60 (e.g., silicon) may have a CTE of 2.8. However, the guard ring 52 (e.g., silicon oxide) may have a CTE of 0.6. As such, the lesser heat expansion of the guard ring 52 as compared to the semiconductor substrate 60 also helps to counterbalance the greater heat expansion of the through via 102 as compared to the semiconductor substrate 60.

Referring to FIGS. 8B through 8D, top-down views illustrate the semiconductor structure 50 at the uppermost portion of the semiconductor substrate 60, in accordance with various embodiments of the guard ring 52 being concentric around the through via 102 while within the keep out zone 102K. As illustrated, the recess 80 is filled with the adhesive layer 102A, the barrier layer 102B, and the conductive material 102C. For the sake of example, FIG. 8B illustrates the guard ring 52 having a square shape, FIG. 8C illustrates the guard ring 52 having a hexagonal shape, and FIG. 8D illustrates the guard ring 52 having a circular shape. Note that the previously described dimensions may refer to locations on these embodiment guard rings 52 that are most proximal to the through via 102 (e.g., edges of the polygons) or most distal to the through via 102 (e.g., corners of the polygons) or there-between.

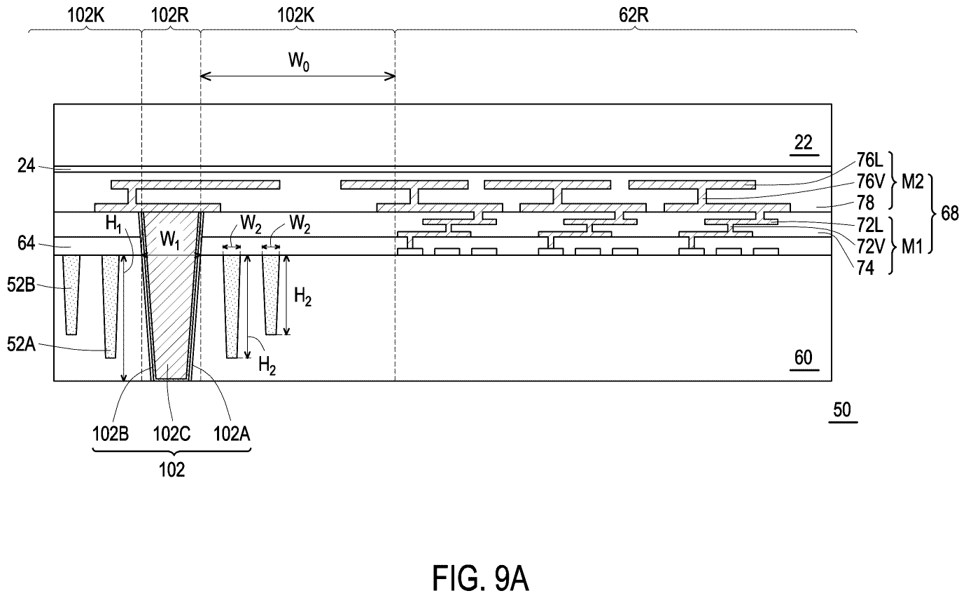

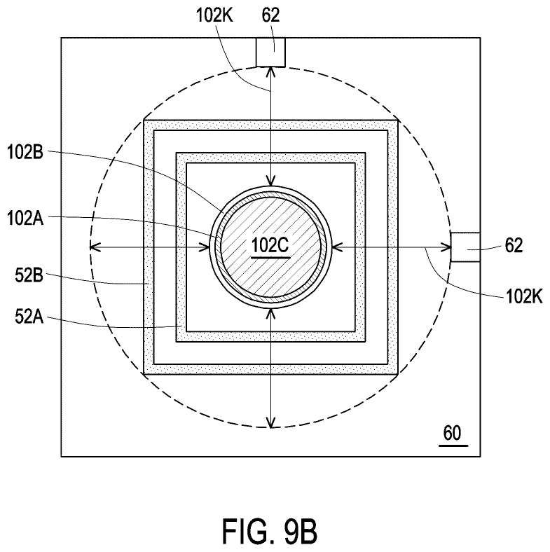

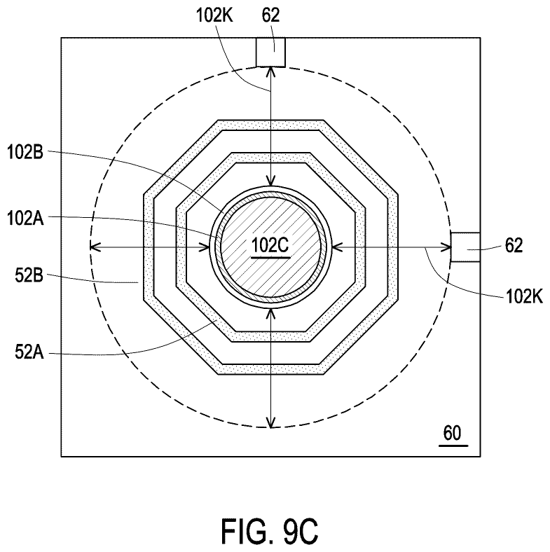

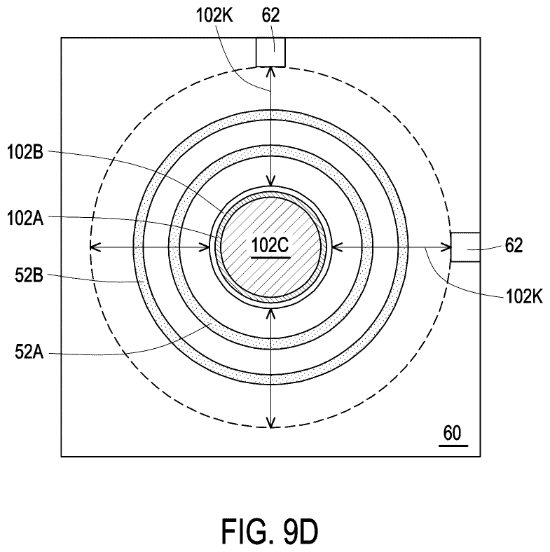

FIGS. 9A through 9D illustrate a multiple guard ring 52 comprising an inner guard ring 52A and an outer guard ring 52B, in accordance with various embodiments. The multiple guard ring 52 structure may provide analogous benefits as described above, albeit being especially useful for through vias 102 that are at the higher ends of the described dimension ranges or greater. Although two rings of the multiple guard ring 52 are illustrated, any feasible number of rings may be utilized. In some embodiments, each of the rings may have dimensions (e.g., the height H₂ and the width W₂) within the ranges described above. For example, the inner guard ring 52A may have greater values than those for the outer guard ring 52B. In other embodiments, the inner guard ring 52A and the outer guard ring 52B may have substantially similar values for those dimensions.

Referring to FIGS. 9B through 9D, top-down views illustrate the semiconductor structure 50 at the uppermost portion of the semiconductor substrate 60, in accordance with various embodiments of the multiple guard ring 52 being concentric around the through via 102 while within the keep out zone 102K. For the sake of example, FIG. 9B illustrates the multiple guard ring 52 having square shapes, FIG. 9C illustrates the multiple guard ring 52 having hexagonal shapes, and FIG. 9D illustrates the multiple guard ring 52 having circular shapes. In addition, any combinations of these shapes maybe utilized with respect to the inner guard ring 52A and the outer guard ring 52B.

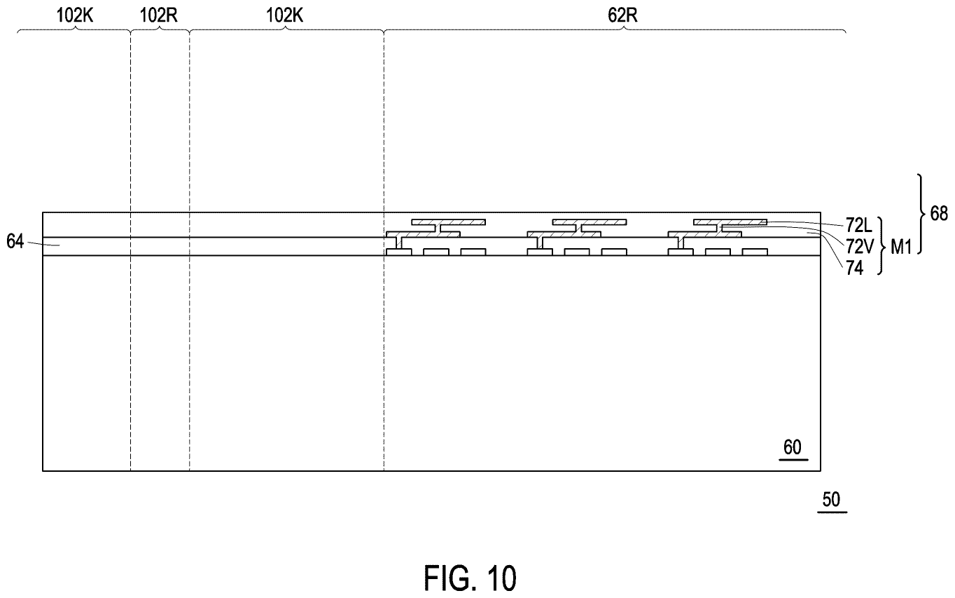

FIGS. 10 through 15D illustrate intermediate steps for forming the semiconductor structure 50 including the through via 102 and the guard ring 52 in a via-last process, in accordance with various embodiments. Note that analogous features may be formed similarly as described above in connection with FIGS. 1A through 9D, unless otherwise specified.

In FIG. 10, devices 62 are formed at the active surface of the semiconductor substrate 60. The devices 62 may be electrical components such as active devices and passive devices. For example, the devices 62 may be transistors, diodes, capacitors, resistors, or the like, formed by any suitable formation method. The devices 62 may be interconnected to form, e.g., memory devices or logic devices on the semiconductor structure 50.

The ILD layers 64 are formed on the semiconductor substrate 60, and electrically conductive features, such as contact plugs 66, are formed physically and electrically coupled to the devices 62. The ILD layers 64 may be formed of any suitable dielectric material, for example, an oxide such as silicon oxide, phosphosilicate glass (PSG), borosilicate glass (BSG), boron-doped phosphosilicate glass (BPSG), or the like; a nitride such as silicon nitride; or the like. The ILD layers 64 may be formed by any suitable method, such as CVD, physical vapor deposition (PVD), ALD, PEALD, PECVD, SACVD, FCVD, spin-on, and/or the like, or a combination thereof. The electrically conductive features in the ILD layers 64 may be formed through any suitable process, such as deposition, damascene (e.g., single damascene, dual damascene, etc.), the like, or combinations thereof.

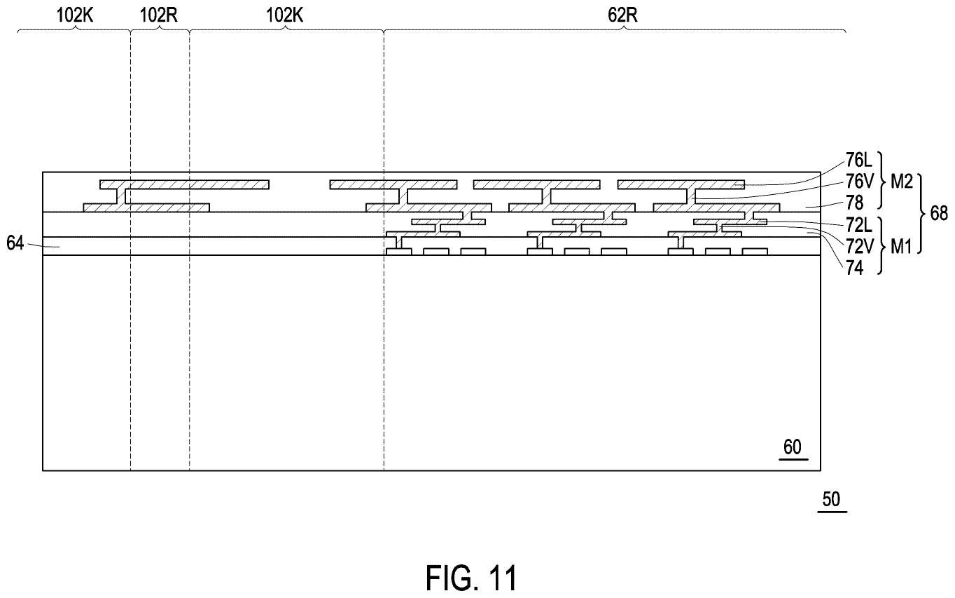

In addition, first metallization layers M1 are formed over the semiconductor substrate 60 and over the ILD layers 64. The first metallization layers M1 are a lower portion of an interconnect structure 68, wherein second metallization layers M2 are subsequently formed (see FIG. 11). The interconnect structure 68 electrically connects the devices 62 to form integrated circuits. First metallization layers M1 comprise conductive features 72 (e.g., conductive vias 72V and lines 72L) embedded in intermetal dielectric (IMD) layer(s) 74 (not individually shown). In addition to providing insulation between various conductive elements, an IMD layer 74 may include one or more dielectric etch stop layers (not individually shown) to control the etching processes that form openings in the IMD layer 74. Generally, vias 72V conduct current vertically and are used to electrically connect two other conductive features 72 (e.g., conductive lines 72L) located at vertically adjacent levels, whereas lines 72L conduct current laterally and are used to distribute electrical signals and power within one level.

Although two layers of conductive features 72 (e.g., two layers of the conductive lines 72L) are illustrated among the first metallization layers M1, it should be appreciated that more or fewer layers may be formed. Each of the first metallization layers M1 includes metallization patterns of conductive lines 72L in the corresponding IMD layer 74. The conductive features 72 are electrically coupled to the devices 62 along the semiconductor substrate 60. The first metallization layers M1 of the interconnect structure 68 may be formed by a damascene process, such as a single damascene process, a dual damascene process, or the like. In the illustrated embodiments, lowermost conductive lines 72L of the conductive features 72 connect contact plugs 66 to other conductive features 72, and vias 72V connect conductive lines 72L on a level below the vias 72V to conductive lines 72L above the vias 72V (e.g., a pair of lines 72L can be connected by a via 72V). Some embodiments may adopt a different scheme. For example, conductive vias 72V may be in the first metallization layers M1 between the contact plugs 66 and the conductive features 72. In some embodiments, the contact plugs 66 are formed through the ILD layers 64 before or during the formation of the metallization layers M1.

Still referring to FIG. 10, the first metallization layers M1 may be formed using, for example, a damascene process flow. The techniques used to deposit the dielectric stack for the IMD layers 74 may be the same or similar as those used in forming the ILD layers 64. Appropriate photolithography and etching techniques (e.g., anisotropic RIE employing fluorocarbon chemicals) may be used to pattern each of the IMD layers 74 to form openings for respective conductive lines 72L and/or vias 72V. Several conductive materials may be deposited to fill the trenches forming the conductive features 72 of the first metallization layers M1. For example, the openings may be first lined with one or more liners and then filled with a conductive fill layer. A conductive diffusion barrier liner may be formed over sidewalls and bottom surfaces of the trenches. Any excess conductive material over the IMD layer 74 outside of the openings may be removed by a planarizing process (e.g., CMP) thereby forming a top surface comprising dielectric regions of IMD layer 74 that are substantially coplanar with the conductive features 72. As a result, the first metallization layers M1 comprise the conductive features 72 (e.g., conductive lines 72L and vias 72V) embedded in the IMD layers 74.

In some embodiments, one or more layers of the first metallization layers M1 may be formed using, for example, a dual damascene process flow. First, a dielectric stack used to form the IMD layer 74 is formed using similar materials and methods as described above. Next, openings for vias and lines are formed in the IMD layer 74 with appropriate photolithography and etching techniques. The openings for vias may be vertical holes extending through the IMD layer 74 to expose a top surface of the lower conductive features 72 (e.g., the lowermost conductive lines 72L of the first metallization layers M1), and the openings for conductive lines 72L may be longitudinal trenches formed in an upper portion of the IMD layer 74. The openings may be formed using either a via-first process or a via-last process.

Several conductive materials may be deposited to fill the holes and trenches simultaneously forming a layer of the conductive lines 72L and vias 72V of the first metallization layers M1. The conductive lines 72L and vias 72V may be formed using similar materials and methods as described above. Any excess conductive material over the IMD 74 outside of the openings may be removed by a planarization process (e.g., CMP) thereby forming a top surface comprising dielectric regions of IMD layers 74 that are substantially coplanar with the conductive features 72 of the first metallization layers M1. As a result, the first metallization layers M1 include a plurality of layers of the conductive features 72 embedded in a plurality of the IMD layers 74.

Although the guard rings 52 (and the through vias 102) will be subsequently formed through the back side of the semiconductor substrate 60, the through via region 102R, the keep out zone 102K, and the device region 62R are labeled. Despite a different method of fabrication and different orientations of certain components, the components of the present embodiments will follow analogous configurations as described above. For example, the first metallization layers M1 may remain free of the conductive features 72 within the through via region 102R and the keep out zone 102K. In some embodiments (not specifically illustrated), the first metallization layers M1 may include conductive features 72 within the through via region 102R in order to be electrically connected to the subsequently formed back side through vias 102.

In FIG. 11, second metallization layers M2 are formed over the first metallization layers M1 to form an upper portion of the interconnect structure 68. Although two layers of the second metallization layers M2 are illustrated, the second metallization layers M2 represent any number of layers for simplicity of illustration. Any suitable number of metallization layers may be formed in the interconnect structure 68, such as four to twenty metallization layers in the first metallization layers M1 and the second metallization layers M2 combined. The second metallization layers M2 comprise IMD layers 78 and conductive features 76 (e.g., conductive lines 76L and vias 76V). The materials and processing techniques described above in the context of the first metallization layers M1 may be used to form the second metallization layers M2 (e.g., including the analogous features).

In various embodiments, the conductive features 76 of the second metallization layers M2 will be electrically connected to the subsequently formed through vias 102. For example, lowermost conductive features 76 (e.g., lowermost conductive lines 76L) may be formed along top surfaces of the through vias 102 to make electrical connection. In other embodiments (not specifically illustrated), the second metallization layers M2 may be electrically connected to the through vias by the conductive vias 76V. Similarly as stated above, the conductive features 76 may be formed using a dual damascene process (or a combination of single and dual damascene processes). In some embodiments, a first of these dual damascene processes may include forming the uppermost vias 72V (e.g., through an uppermost IMD layer 74) of the first metallization layers M1 simultaneously with the lowermost conductive lines 76L (e.g., through a lowermost IMD layer 78) of the second metallization layers M2.

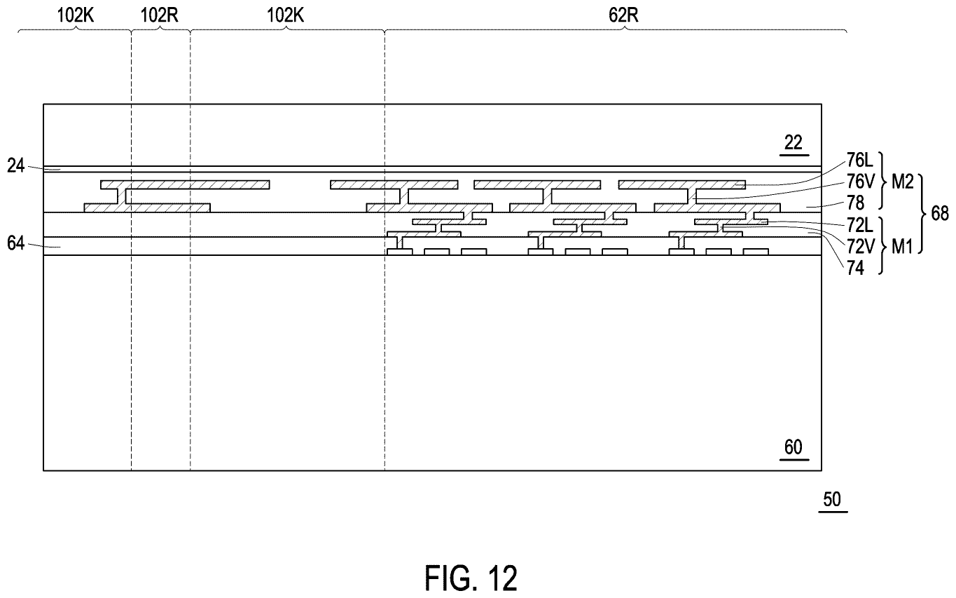

In FIG. 12, the semiconductor structure 50 is attached to carrier 22 and release film 24. The carrier 22 may be a glass carrier, a silicon wafer, an organic carrier, or the like. The carrier 22 may have a round top-view shape in accordance with some embodiments. The release film 24 may be a glue and may be formed of a polymer-based material and/or an epoxy-based thermal-release material (such as an LTHC material), which is capable of being decomposed under radiation such as a laser beam, so that the carrier 22 may be subsequently de-bonded from the overlying structure. In accordance with some embodiments, the release film 24 is applied on the carrier 22 through coating before attaching the carrier 22 to the semiconductor structure 50.

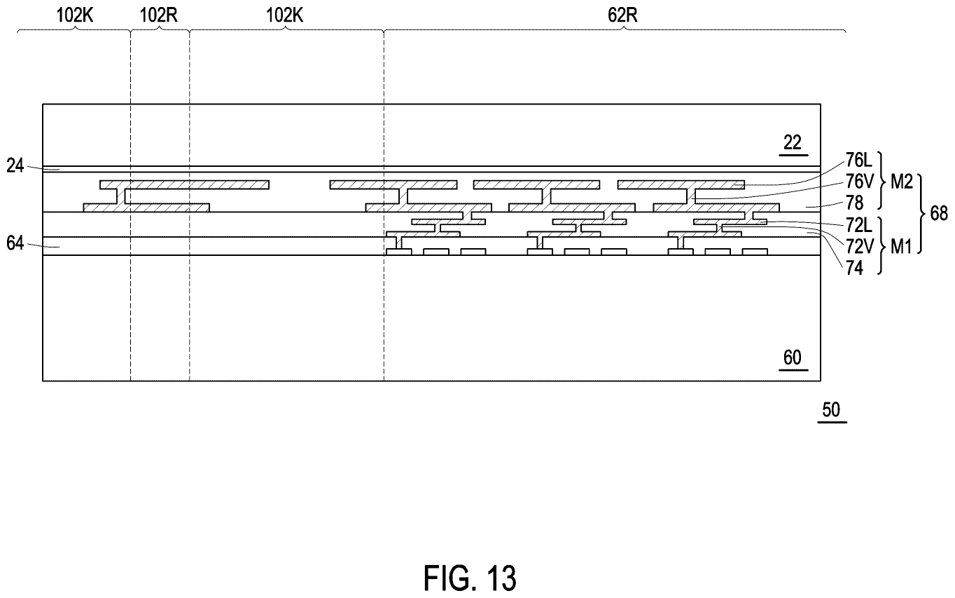

In FIG. 13, a back side thinning process is performed on the back side of the semiconductor structure 50, wherein the semiconductor substrate 60 is thinned to a desired thickness. The back side thinning process may be a grinding process and performed through a CMP process or a mechanical polishing process.

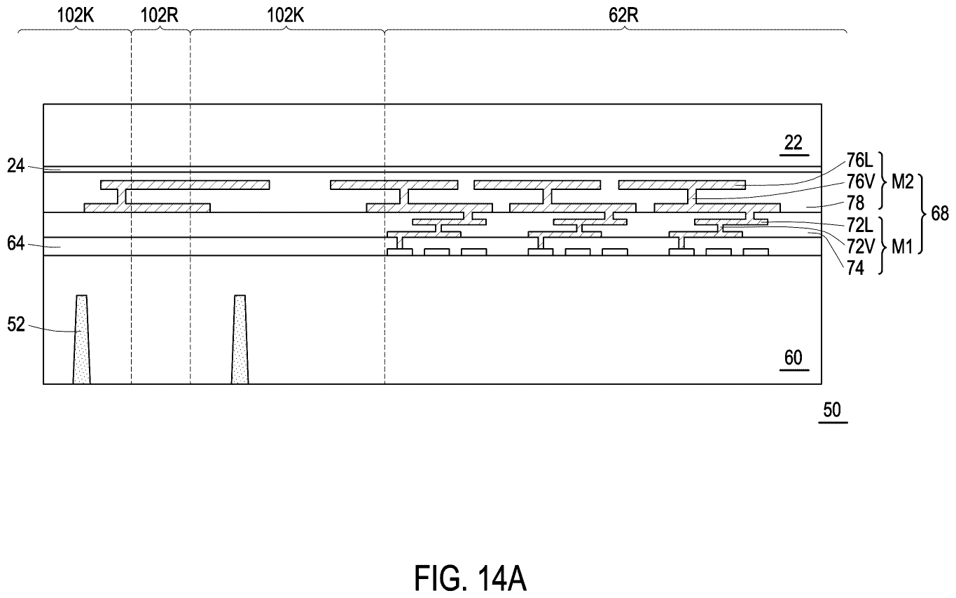

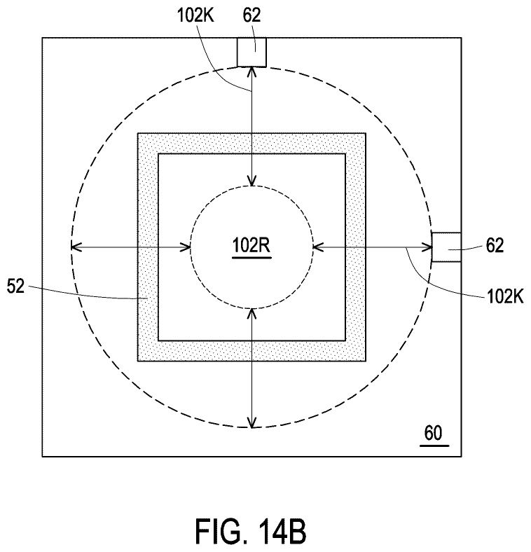

In FIGS. 14A and 14B, a guard ring 52 (e.g., a back side guard ring) is formed in the semiconductor substrate 60. The guard ring 52 will encircle the subsequently formed through via 102. In accordance with various embodiments, the guard ring 52 comprises a dielectric material and be referred to as a dielectric guard ring or an insulating guard ring. Note that this and subsequent figures illustrate one guard ring 52 (e.g., encircling one through via), however, any number of guard rings 52 and through vias 102 may be utilized in the semiconductor structure 50.

As previously discussed, the guard ring 52 is located within a region that will be around the subsequently formed through via 102 (e.g., the keep out zone (KOZ) 102K), which surrounds the through via 102 (e.g., currently indicated as through via region 102R). In accordance with various embodiments, the keep out zone may have a width W₀ by which the most proximal devices 62 are separated from the through via region 102R (e.g., subsequently formed through via 102).

Appropriate photolithography and etching techniques (e.g., RIE employing fluorocarbon chemicals) may be used to etch the semiconductor substrate 60 to form an opening for the guard ring 52. A dielectric material may be deposited to fill the opening. For example, the dielectric material may include an oxide or a nitride, such as silicon oxide, silicon oxycarbide, silicon oxynitride, silicon nitride, the like, or a combination thereof. Any excess dielectric material over the semiconductor substrate 60 outside of the opening may be removed by a planarization process, such as a CMP process, thereby forming a top surface of the guard ring 52 that is substantially coplanar with the semiconductor substrate 60.

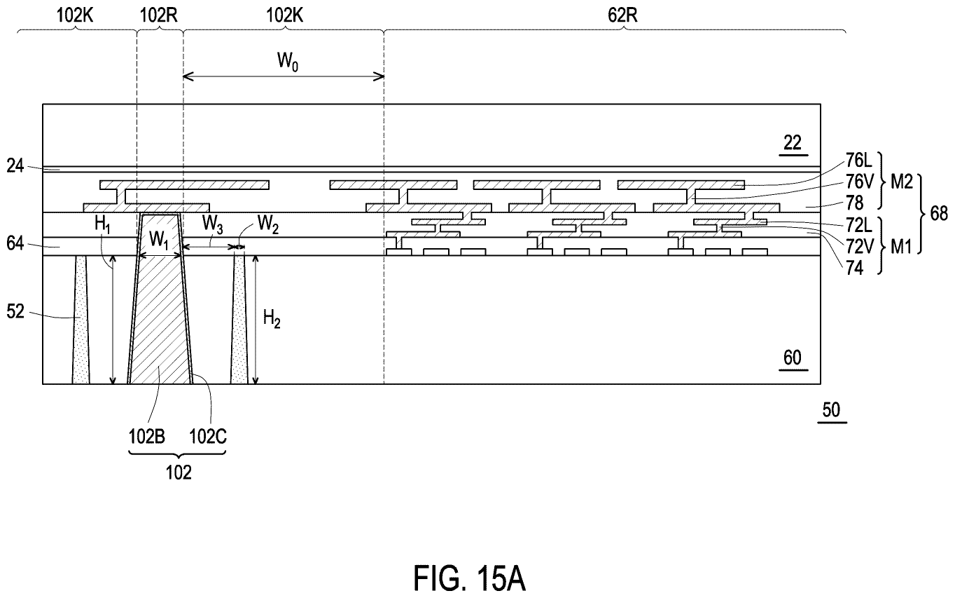

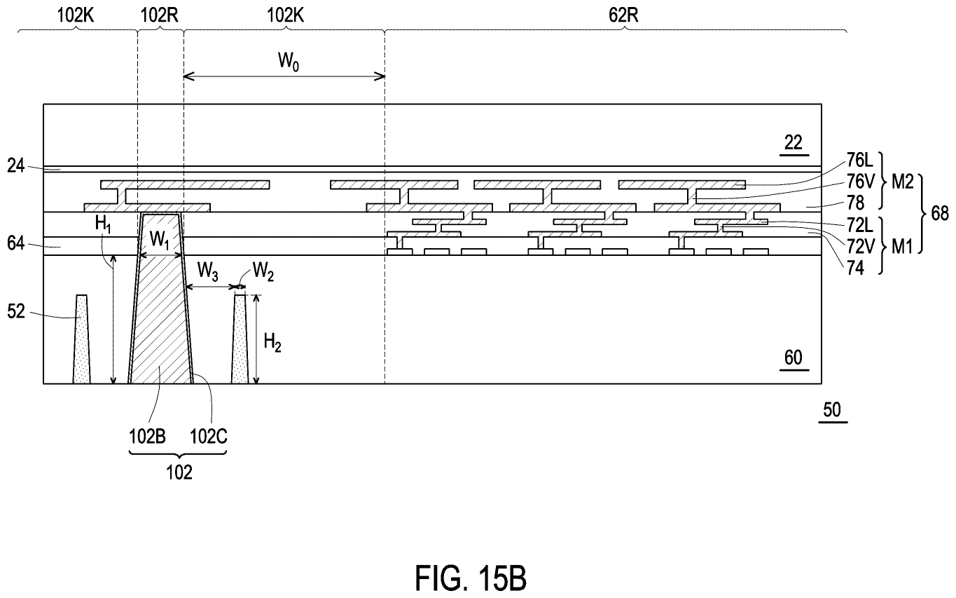

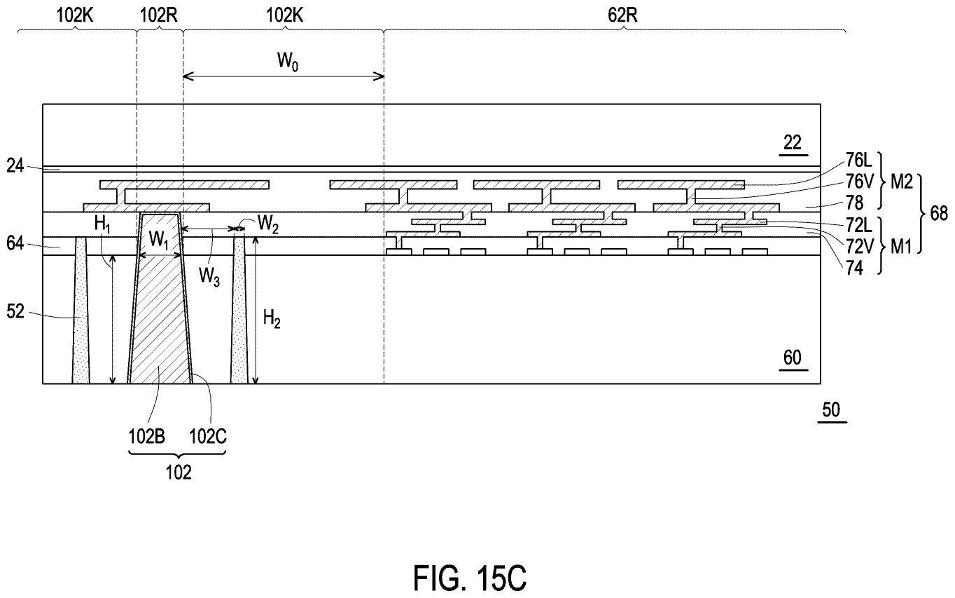

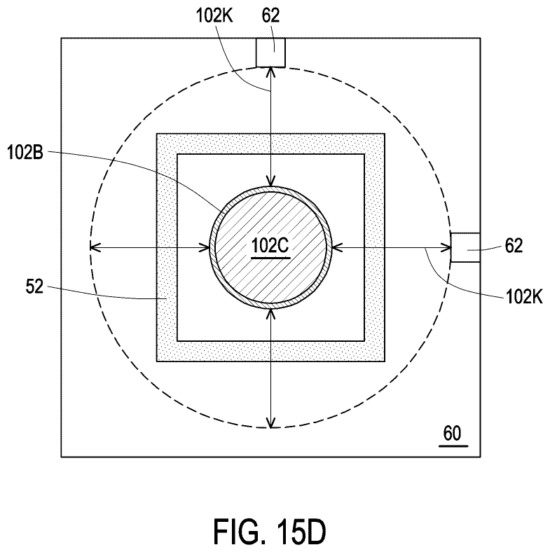

Although the guard ring 52 is illustrated as extending to a depth that is the same thickness as the thickness of the semiconductor substrate 60, other depths may be utilized. For example, the guard ring 52 may extend less than that thickness (see FIG. 15B) or greater than that thickness (see FIG. 15C).

Referring to FIG. 14B, a plan view illustrates the semiconductor structure 50, albeit not necessarily at any particular cross-section of the semiconductor substrate 60. Instead, this plan view (and the subsequent plan views for the present embodiments) illustrates lateral relationships between the various components. The illustrated components may be within a same horizontal cross-section or they may be in different cross-sections. As illustrated, the guard ring 52 forms a concentric ring around the through via region 102R within the keep out zone 102K. The guard ring 52 is illustrated as being rectangular (e.g., square). However, the guard ring 52 may be any suitable polygon (e.g., square, hexagonal, octagonal, etc.) or oval (e.g., circular) (see FIGS. 8B through 8D above). In addition, the keep out zone 102K is illustrated as a concentric circle around the through via region 102R. However, the keep out zone 102K may be any suitable shape, such as a rectangle (e.g., square).

In FIGS. 15A and 15B, through vias 102 are formed using a via-last process, in accordance with various embodiments. As illustrated, the through vias 102 extend through a back side of the semiconductor substrate 60 and the ILD layers 64, and may further extend through the first metallization layers M1 (e.g., the IMD layers 74) to electrically connect to the second metallization layers M2. Similarly as described above, the through vias 102 can be used for electrical connection of devices subsequently attached to the semiconductor structure 50, such as components that are or will be located on opposite sides of the semiconductor substrate 60. For example, the through vias 102 may be formed through multiple layers for the electrical connection of components formed or attached outside the semiconductor structure 50. Although only one through via 102 is illustrated for exemplary purposes, any suitable number of through vias 102 may be formed. In addition, although only an individual through via 102 is illustrated within an individual guard ring 52, in some embodiments, a plurality of through vias 102 may be located within an individual keep guard ring 52. Further, the figures illustrate the through vias 102 as extending through the first metallization layers M1 for illustrative purposes. In some embodiments, the through vias 102 may be formed to be directly connected to the first metallization layers M1. In particular, the through vias 102 may be formed through any suitable number of metallization layers.

For example, backside recesses are formed through the back side of the semiconductor substrate 60. The recesses may be formed by applying, exposing, and developing a suitable photoresist (not shown) over the semiconductor substrate 60 to define a desired pattern of through vias. A first etching process may be used to remove portions of the semiconductor substrate 60 to expose the ILD layers 64. One or more additional etching processes may be used to extend the recesses to the desired depth. Other techniques, such as milling, laser techniques, a combination thereof, and/or the like, may also be used. The recesses may be formed so as to extend through the semiconductor substrate 60 and beyond the devices 62 (e.g., exposing a conductive line 72L of the second metallization layers M2).

In addition, a barrier layer 102B may be conformally deposited in the recesses without first forming an adhesive layer 102A. For example, the barrier layer 102B may be formed by CVD, ALD, PVD, thermal oxidation, the like, or a combination thereof. The barrier layer 102B may be formed from an oxide, a nitride, or an oxynitride, such as titanium nitride, titanium oxynitride, tantalum nitride, tantalum oxynitride, tungsten nitride, a combination thereof, and/or the like. However, any suitable material for the barrier layer 102B may be used. In some embodiments, the barrier layer 102B is formed directly along the sidewalls and bottom of the recesses. The barrier layer 102B may have a thickness in a range of 5 nm to 500 nm. As such, the barrier layer 102B may be the only liner layer. However, any suitable number and type of liner layers may be utilized for the back side through via 102.

Finally, after forming the liner layer(s) (e.g., the barrier layer 102B), the remainder of the recesses may be filled with a conductive material 102C. The conductive material 102C may comprise copper, tungsten, cobalt, aluminum, silver, gold, alloys, doped polysilicon, the like, or a combination thereof. The conductive material 102C may be formed by deposition or electroplating copper onto a seed layer (not shown), filling and overfilling the recesses. However, any suitable process such as CVD, PVD, or the like may be used. Once the recesses have been filled, excess of the barrier layer 102B, seed layer (if present), and conductive material 102C outside of the recesses may be removed through a planarization process such as CMP, although any suitable removal process may be used. Remaining portions of the barrier layer 102B and the conductive material 102C form the back side through vias 102. In some cases, only the conductive materials remaining in the recesses may be referred to as the through vias 102. As such, the through vias 102 may include only the conductive material 102C or include the conductive material 102C and the barrier layer 102B.

Benefits are achieved through the guard ring 52 encircling the through via 102, similarly as described above in connection with the previous embodiments. In particular, the layout and dimensions of the guard ring 52 in relation to the corresponding through via 102 provide advantages to the performance of the resulting semiconductor structure 50. In various embodiments, a height H₁ of the through via 102 within the semiconductor substrate 60 (e.g., the thickness of the semiconductor substrate 60) may be greater than a total height H₂ of the guard ring 52 within the semiconductor substrate 60.

In accordance with various embodiments, the height H₁ may be greater than or equal to 5 μm, and the height H₂ may be greater than or equal to 0.5 μm. In addition, a ratio H₂/H₁ may range from 0.5 to about 1.2 (or substantially 1). For example, FIG. 15A illustrates embodiments in which this ratio is substantially 1, FIG. 15B illustrates embodiments in which this ratio is greater than or equal to 0.5 and less than 1, and FIG. 15C illustrates embodiments in which this ratio is greater than 1 and less than or equal to 1.2. Similarly as with the previous embodiments, the through vias 102 may have a taper angle α₁ being less than 90°. In addition, the guard ring 52 may have a taper angle α₂ being less than 90°. Note that taper angles α₁ and α₂ are opposite of the previous embodiments due to these features being formed from the back side of the semiconductor substrate 60. In some embodiments, the through vias and/or the guard ring are substantially vertical (e.g., taper angles of) 90°. However, any suitable shape for the through via 102 and the guard ring 52 may be used.

As noted above, the keep out zone may have width W₀ by which the most proximal devices 62 are separated from the through via 102. In addition, the through via 102 and the guard ring 52 may have similar proportions. For example, a ratio of the height H₁ to a width W₁ of the through via 102 may range from 2 to 20, and a ratio of the height H₂ to a width W₂ of the guard ring 52 may range from 2 to 20. Further, the guard ring 52 may be separated from the through via 102 by a width W₃. As such, a ratio W₀/W₁ may range from 0.2 to 1.2, a ratio W₃/W₀ may be greater than 0 (such as ranging from 0.05 to 0.2), and a ratio W₂/W₀ may range from 0.1 to 0.5. These dimensions ensure a large enough distances between the various features to reduce expansion issues associated with the various CTE mismatches. Conversely, these dimensions ensure close enough distances between the various features to allow the guard ring 52 to serve as a buffer and mitigate issues specifically relating to the CTE mismatch between the through via 102 and the semiconductor substrate 60.

Referring to FIG. 15D, a plan view illustrates the semiconductor structure 50, albeit not necessarily at any particular cross-section of the semiconductor substrate 60. Instead, this plan view illustrates lateral relationships between the various components. The illustrated components may be within a same horizontal cross-section or they may be in different cross-sections. As illustrated, the guard ring 52 forms a concentric ring around the through via region 102R within the keep out zone 102K. The guard ring 52 is illustrated as being rectangular (e.g., square). However, the guard ring 52 may be any suitable polygon (e.g., square, hexagonal, octagonal, etc.) or oval (e.g., circular) (see FIGS. 8B through 8D above). In addition, the keep out zone 102K is illustrated as a concentric circle around the through via region 102R. However, the keep out zone 102K may be any suitable shape, such as a rectangle (e.g., square).

In addition, FIGS. 9B through 9D above depict plan views of the present embodiments using a multiple guard ring 52. These figures represent the current embodiments, except that the illustrated features may not necessarily be within the same horizontal cross-section.

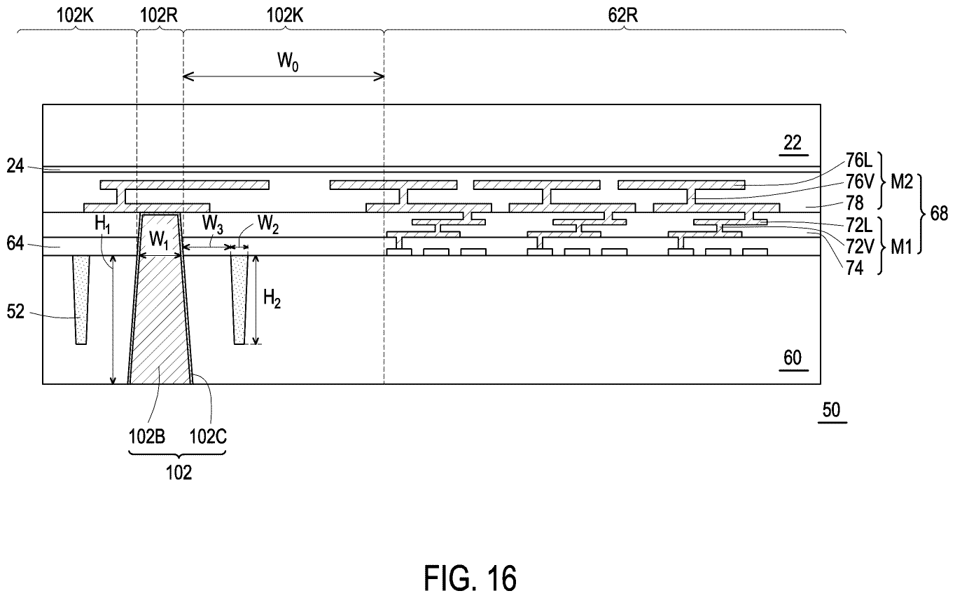

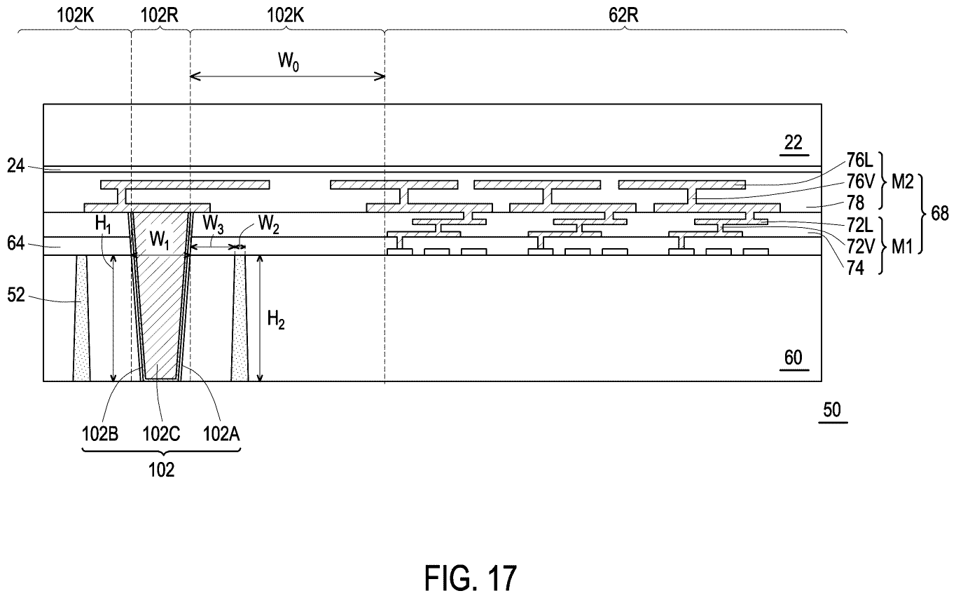

FIGS. 16 and 17 illustrate additional embodiments of the semiconductor structures 50 comprising through vias 102 encircled by dielectric guard rings 52. FIG. 16 illustrates embodiments in which the guard ring 52 is formed through the front side of the semiconductor substrate 60 (e.g., a guard ring first process), and the through via 102 is formed through the back side of the semiconductor substrate 60 (e.g., the via-last process). FIG. 17 illustrates embodiments in which the through via 102 is formed through the front side of the semiconductor substrate (e.g., the via-middle process), and the guard ring 52 is formed through the back side of the semiconductor substrate 60 (e.g., a guard ring last process). The various dimensions and configurations for each of these features in these embodiments may follow the analogous dimensions and configurations described above with respect to the previous embodiments.

Although not specifically illustrated, any of the embodiment semiconductor structures 50 may undergo subsequent processing for incorporation into a semiconductor package. For example, under bump metallurgies (UBMs) and/or conductive connectors may be formed over either side or both sides of the semiconductor structure 50 using any suitable methods. In some such embodiments, redistribution structures may be formed before forming the conductive connectors. The redistribution structures may be formed using any suitable method, such as methods similar to those described above in connection with forming the interconnect structure 68. In addition, a singulation process may be performed by sawing along scribe line regions (not specifically indicated), e.g., between die regions of adjacent integrated circuit dies. The sawing singulates the die regions from one another.

Embodiments may achieve advantages. In particular, forming dielectric guard rings 52 around through vias 102 in accordance with the disclosed embodiments improves performance of the semiconductor structure 50 when CTE mismatches between the through vias 102 and the semiconductor substrate 60 may otherwise cause degradations in performance. For example, the guard ring 52 is formed of a dielectric material having a closer CTE to the semiconductor substrate 60. As such, the guard ring 52 provides an insulating barrier and an expansion buffer between the through vias 102 and the devices 62.

In an embodiment, a method includes: forming a first opening in a semiconductor substrate, in a plan view the first opening having a ring shape; forming a dielectric guard ring in the first opening; forming an active device along a first surface of the semiconductor substrate; forming first metallization layers over the active device; forming a second opening through the semiconductor substrate, the second opening adjacent to the ring shape of the dielectric guard ring; forming a conductive through via in the second opening; and forming second metallization layers over the first metallization layers. In another embodiment, the first opening is formed through the first surface of the semiconductor substrate. In another embodiment, the second opening is formed through the first surface of the semiconductor substrate. In another embodiment, the first opening is formed through a second surface of the semiconductor substrate, and wherein the second surface is opposite of the first surface. In another embodiment, the second opening is formed through the second surface of the semiconductor substrate, and wherein the second opening exposes the second metallization layers. In another embodiment, after forming the second metallization layers, a first height of the dielectric guard ring within the semiconductor substrate is less than a second height of the through via within the semiconductor substrate. In another embodiment, the first height is greater than twice a first width of the dielectric guard ring, wherein the first width is measured at the first surface of the semiconductor substrate, wherein the second height is greater than twice a second width of the through via, and wherein the second width is measured at the first surface of the semiconductor substrate. In another embodiment, the semiconductor substrate comprises a keep out zone based on the through via, and wherein an entirety of the dielectric guard ring is located within the keep out zone.

In an embodiment, a semiconductor device includes: an active device along a first surface of a semiconductor substrate; first metallization layers over and electrically connected to the active device, the first metallization layers comprising conductive features embedded in first dielectric layers; a through via extending through the semiconductor substrate; second metallization layers over and electrically connected to the first metallization layers and the through via; and a dielectric guard ring embedded in the semiconductor substrate, in a plan view the dielectric guard ring encircling the through via. In another embodiment, a width of the through via at the first surface is greater than a width of the through via at a second surface of the semiconductor substrate. In another embodiment, a width of the through via at the first surface is less than a width of the through via at a second surface of the semiconductor substrate. In another embodiment, in the plan view the dielectric guard ring has a polygonal shape. In another embodiment, in the plan view the dielectric guard ring has a circular shape. In another embodiment, the semiconductor device further includes an additional dielectric guard ring, wherein in the plan view the additional dielectric guard ring encircles the dielectric guard ring.

In an embodiment, semiconductor device includes: an active device along a front side surface of a semiconductor substrate, the semiconductor substrate having a thickness; a through via embedded in the semiconductor substrate, the through via having a first width at the front side surface, the through via having a first height within the semiconductor substrate; a dielectric guard ring embedded in the semiconductor substrate and encircling the through via, the dielectric guard ring having a second width at a location most proximal or at the front side surface, the dielectric guard ring having a second height; and a metallization layer over the semiconductor substrate, the metallization layer being electrically connected to the active device and the through via. In another embodiment, the second height is greater than the first height. In another embodiment, the first height is equal to the second height. In another embodiment, a first end of the dielectric guard ring is level with a back side of the semiconductor substrate, and wherein the second height is less than the thickness of the semiconductor substrate. In another embodiment, the active device is a first distance from the through via measured along the front side surface of the semiconductor substrate, wherein the dielectric guard ring is a second distance from the through via, and wherein a ratio of the second distance to the first distance is between 0.05 and 0.2. In another embodiment, a first ratio of the first height to the first width is substantially the same as a second ratio of the second height to the second width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a ring opening through at least a portion of a semiconductor substrate, the ring opening having a first depth;
filling the ring opening with a dielectric material to form a dielectric ring;
forming active devices along a first side of the semiconductor substrate;
forming a first interconnect structure over the active devices, the first interconnect structure comprising first metallization layers embedded in first dielectric layers;
forming a through substrate via (TSV) opening through at least a portion of the semiconductor substrate, the TSV opening having a second depth; and
filling the TSV opening with a second dielectric material and a conductive material to form a TSV, wherein in a plan view the dielectric ring encircles the TSV.

2. The method of claim 1, wherein forming the ring opening comprises forming the ring opening through the first side of the semiconductor substrate, and wherein forming the TSV opening comprises forming the TSV opening through the first side of the semiconductor substrate.

3. The method of claim 1, wherein forming the ring opening comprises forming the ring opening through the first side of the semiconductor substrate, wherein forming the TSV opening comprises forming the TSV opening through a second side of the semiconductor substrate, wherein the second side is opposite the first side.

4. The method of claim 1, wherein forming the ring opening comprises forming the ring opening through a second side of the semiconductor substrate, the second side being opposite the first side, and wherein forming the TSV opening comprises forming the TSV opening through the first side of the semiconductor substrate.

5. The method of claim 1, wherein forming the ring opening comprises forming the ring opening through a second side of the semiconductor substrate, the second side being opposite the first side, and wherein forming the TSV opening comprises forming the TSV opening through the second side of the semiconductor substrate.

6. The method of claim 1, wherein the second depth is greater than the first depth, and wherein the dielectric material comprises an oxide.

7. The method of claim 1, further comprising:
forming a second interconnect structure over the first interconnect structure and the TSV, the second interconnect structure comprising second metallization layers embedded in second dielectric layers; and
thinning a second side of the semiconductor substrate to expose the TSV, the second side being opposite the first side.

8. The method of claim 7, wherein the second interconnect structure is electrically coupled to the TSV and the first interconnect structure.

9. A method of forming a semiconductor device, the method comprising:
forming a transistor in a front side of a semiconductor substrate;
forming a guard ring opening in the front side of the semiconductor substrate;
filling the guard ring opening with an oxide to form a guard ring in the semiconductor substrate;
forming an inter-layer dielectric over the transistor and the guard ring;
forming a contact plug through the inter-layer dielectric to the transistor;
forming a through via opening in the inter-layer dielectric and the front side of the semiconductor substrate;
filling the through via opening with a conductive material to form a through via; and
forming an interconnect structure over the through via and the contact plug.

10. The method of claim 9, wherein forming the through via opening comprises etching the semiconductor substrate to a depth that is greater than a depth of the guard ring.

11. The method of claim 9, wherein the guard ring surrounds the through via opening, and wherein in a plan view the guard ring has a circular ring shape or a polygonal ring shape.

12. The method of claim 9, wherein forming the guard ring opening comprises a reactive-ion etching process, and further comprising after filling the guard ring opening with the oxide, planarizing the guard ring to be level with the semiconductor substrate.

13. The method of claim 9, wherein filling the through via opening comprises:
forming a dielectric adhesive layer along inner walls of the through via opening;
forming a barrier layer over the dielectric adhesive layer; and
forming a conductive fill material over the barrier layer.

14. The method of claim 13, wherein forming the conductive fill material comprises:
depositing a seed layer along the barrier layer; and
electroplating copper over the seed layer.

15. A method of forming a semiconductor device, the method comprising:
forming active devices in an active region of a front side of a semiconductor substrate, the active region being adjacent to a device free zone of the front side of the semiconductor substrate;
forming a front side interconnect structure over the active devices;
thinning a back side of the semiconductor substrate;
forming a through via opening through the back side of the semiconductor substrate, the through via opening extending through a dielectric guard ring embedded in the semiconductor substrate; and
forming a through via in the through via opening.

16. The method of claim 15, further comprising, before forming the front side interconnect structure, forming the dielectric guard ring, wherein forming the dielectric guard ring comprises:
forming a guard ring opening in the device free zone of the front side of the semiconductor substrate;
filling the guard ring opening with an oxide material; and
planarizing the oxide material to be level with the semiconductor substrate.

17. The method of claim 16, wherein the through via extends through an entirety of a remaining thinned semiconductor substrate, and wherein the dielectric guard ring extends through less than the entirety of the remaining thinned semiconductor substrate.

18. The method of claim 17, wherein the dielectric guard ring fully interposes the through via and a most proximal device of the active devices.

19. The method of claim 15, further comprising, after thinning the back side of the semiconductor substrate, forming the dielectric guard ring, wherein forming the dielectric guard ring comprises:
forming a guard ring opening through the back side of the semiconductor substrate;
filling the guard ring opening with an oxide material; and
planarizing the oxide material to be level with the semiconductor substrate.

20. The method of claim 19, wherein the through via extends through an entirety of a remaining thinned semiconductor substrate, and wherein the dielectric guard ring extends through less than the entirety of the remaining thinned semiconductor substrate.
